(19) United States
(12) Patent Application Publication
(10) Pub. No.: US 2007/0076819 A1
(43) Pub. Date: Apr. 5, 2007

(54) 8VSB bandwidth-limited peak filter

(75) Inventor: David L. Hershberger, Nevada City, CA (US)

Correspondence Address: THE WEBB LAW FIRM, P.C., 700 KOPPERS BUILDING, 436 SEVENTH AVENUE, PITTSBURGH, PA, 15219, US

(73) Assignee: Axcera, LLC, Lawrence, PA (US)

(21) Appl. No.: 11/528,798

(22) Filed: Sep. 28, 2006

Related U.S. Application Data
(60) Provisional application No. 60/722,194, filed on Sep. 30, 2005.

(51) Int. Cl. H03D 1/24

(52) U.S. Cl. 375/321

(57) ABSTRACT

In an 8-level vestigial sideband (8VSB) filter and method, a bandpass filter processes an input signal to produce a first bandpass filtered output signal. A center clipper circuit is responsive to first and second threshold values and the first bandpass filtered output signal to produce a center clipper output signal that has (1) zero amplitude when the bandpass filtered output signal has an amplitude that is between the first and second threshold values and (2) an amplitude equal to an amplitude of the bandpass filtered output signal minus a value of one of the threshold values otherwise. A summing circuit is responsive to the combination of the center clipper output signal and the first bandpass filtered output signal to produce a summing circuit output signal. The first bandpass filter output signal is a square root raised cosine filter output signal.

### CROSS REFERENCE TO RELATED APPLICATION

This application claims priority from U.S. Provisional Patent Application No. 60/722,194, filed Sep. 30, 2005, the contents of which are incorporated herein by reference.

### BACKGROUND OF THE INVENTION

1. Field of the Invention

The present invention relates to an 8VSB filter for use in digital television broadcast transmitters.

2. Description of Related Art

In ATSC (Advanced Television Systems Committee) 8VSB (8 level vestigial sideband) digital television broadcast transmitters, there is often a tradeoff made between transmitter output power and nonlinear distortion.

FIG. 1 shows a graph of peak to average ratio versus the log₁₀ of different probability levels. As can be seen from this graph, the peak-to-average ratio of 8VSB signals is approximately 8 dB at low probability levels (less than 0.0001%). However, the peak-to-average ratio of 8VSB signals is often described as being approximately 6 dB, as it is at about the 0.1% probability level. In other words, the peak-to-average ratio exceeds 6 dB only about 0.1% of the time.

Sizes of solid state transmitters are determined by the peak power they are designed to supply, not the average power. If a transmitter is designed to output signals having an 8 dB peak-to-average ratio instead of 6 dB peak-to-average ratio for the same average power, then the output devices of such transmitter would need to be approximately 60% larger than the output devices of a transmitter designed to output signals having a 6 dB peak-to-average ratio. This can increase the cost of the output drivers and, hence, the power consumption of the transmitter, for little practical improvement. In addition to being larger and more expensive, transmitters that utilize linear amplifiers operated at a higher peak-to-average ratios would also be less efficient.

Therefore, most solid state digital television transmitters are operated at levels where clipping occurs on the peaks of the output signal. This clipping reduces the signal-to-noise ratio (SNR) and the modulation error ratio (MER), but not so much as to have a significant effect on the coverage area. If the increased power of the transmitter exceeds the increased distortion power, then the transmitter's coverage area will actually increase, even though transmitted SNR may be slightly decreased.

Simply allowing output signals of the power amplifier stages of transmitters to clip introduces odd order intermodulation components. Heretofore, such components were removed by a combination of nonlinear precorrection and high level bandpass filtering (mask filtering) at the transmitter's output.

U.S. Pat. No. 4,134,074 (hereinafter “the '074 patent”), which is incorporated herein by reference, describes a method of overshoot control in low pass filters. This method may be expanded to bandpass filters processing either real intermediate frequency (IF) signals or complex baseband signals.

The '074 patent discloses that if a band limited but overshooting signal is clipped and then linear phase filtered to the same bandwidth, overshoot will be reduced but not eliminated. If the process is repeated for each iteration of clipping and linear phase filtering, the overshoot can be reduced. After 10 to 20 of such iterations, the overshoot can be reduced to an acceptable amount.

Such a process, however, is complicated and expensive. The '074 patent discloses a method of reducing overshoot that comes close to convergence in just one iteration. Specifically, rather than iteratively clipping, filtering, clipping, filtering, etc., the '074 patent discloses a process that applies a nonlinearity which is “more than clipping” just once, followed by a single linear phase post-filter to control bandwidth.

To apply “more than clipping,” a so-called “center clipper” is used. A center clipper is a well-known device whose output is zero for an input between positive and negative thresholds applied to the device. Above either threshold, however, the output of the center clipper is equal to the input minus the threshold.

For example, consider a center clipper with thresholds of +/−1 volt. If +0.9 volts is applied, the output is zero. If −0.9 volts is applied, the output is zero. If 1.2 volts is applied, the output is 0.2 volts, i.e., +1.2 volts −+1.0 volts. If −1.1 volts is applied, the output is −0.1 volts, i.e., −1 volt −−1.1 volt. As a result, just the unwanted peaks will emerge from the center clipper. If the center clipper's output is simply subtracted from the input, the result is the same as an ordinary clipper. But, if the center clipper's output is amplified and then subtracted from the input, the result is “more than clipping.”

With reference to FIG. 2, a block diagram of a prior art filter for use in FM broadcasting is shown. Competitive considerations require maximum loudness (accurate peak control), but FM stereo modulation also requires accurate bandwidth control (filtering) to avoid aliasing between the L+R and L−R stereo sum and difference signals. In the filter shown in FIG. 2, an amplitude limited input signal (typically from an audio processor, which often produces clipping) is applied to a low pass filter 2. Low pass filter 2 will ring and overshoot, producing overmodulation if not corrected. A center clipper 4 set at 100% modulation nonlinearly separates the overshoots from the filter output. The overshoots are amplified by amplifier 6 by a factor of approximately 2 (6 dB), and then they are subtracted by summing circuit 8 from the output of the low pass filter 2. The result is ringing and overshoot which is mirrored below the 100% modulation level, instead of going beyond the 100% level. When this signal is processed by a linear phase low pass filter 10, the filter output will have very low overshoot.

### SUMMARY OF THE INVENTION

The invention is an 8-level vestigial sideband (8VSB) filter comprising a bandpass filter for processing an input signal to produce a first bandpass filtered output signal; a center clipper circuit responsive to first and second threshold values and the first bandpass filtered output signal to produce a center clipper output signal that has (1) zero amplitude when the bandpass filtered output signal has an amplitude that is between the first and second threshold values and (2) an amplitude equal to an amplitude of the bandpass filtered output signal minus a value of one of the threshold values when the bandpass filtered output signal has an amplitude that is not between the first and second threshold values; and a summing circuit having a first input responsive to the center clipper output signal and a second input responsive to the first bandpass filtered output signal for producing a summing circuit output signal related to the center clipper output signal and the first bandpass filtered output signal.

The filter can include an amplifier for amplifying the center clipper output signal and for providing said amplified center clipper output signal to the first input of the summing circuit. The summing circuit can subtractively combine the amplified center clipper output signal and the first bandpass filtered output signal to produce the summing circuit output signal.

The filter can further include another bandpass filter operative for bandpass filtering the summing circuit output signal to produce a second bandpass filtered output signal.

The filter can further include at least one of the following: another bandpass filter operative for bandpass filtering the amplified center clipper output signal and for outputting the bandpass filtered amplified center clipper output signal to the first input of the summing circuit; and a delay circuit operative for delaying the arrival of the bandpass filtered output signal at the second input of the summing circuit.

The amplifier can have a gain of about 2.

Low frequencies that can be attenuated by the bandpass filter include ω<ω_{c}(1−α). Middle frequencies passable by the bandpass filter include ω_{c}(1−α)<ω<ω_{c}(1+α). High frequencies that can be attenuated by the bandpass filter include ω<ω_{c}(1−α). In the foregoing, ω is a frequency passable by the bandpass filter; ω_{c} is the center frequency of the bandpass filter; and 0<α<1.

The bandpass filter can be a square root raised cosine bandpass filter. The gain at the middle frequencies passable by the square root raised cosine bandpass filter can be constant. The gain at frequencies on opposites sides of the middle frequencies passable by the square root raised cosine bandpass filter can vary (be attenuated) according to a square root raised cosine function.

The invention is also an 8-level vestigial sideband (8VSB) filtering method comprising: (a) filtering an input signal to produce a first signal; (b) producing a second signal that has (1) zero amplitude when the first signal has an amplitude that is between first and second threshold values and (2) an amplitude equal to the first signal minus one of the threshold values when the first signal has an amplitude that is not between the first and second threshold values; and (c) producing a third signal that is responsive to the combination of the first signal and the second signal.

The method can further include amplifying the second signal, wherein in step (c) the second signal is the amplified second signal.

Step (c) can include combining the amplified second signal and the first signal to produce the third signal.

The method can further include bandpass filtering the third signal to produce a fourth output signal.

The method can further include at least one of the following: bandpass filtering the amplified second signal, wherein in step (c) the second signal is the bandpass filtered and amplified second signal; or delaying the propagation of the first signal prior to step (c).

The second signal can be amplified by a gain of about 2.

The input signal can be square root raised cosine bandpass filtered. The gain at the middle frequencies of the square root raised cosine bandpass filtered input signal can be constant. The gain at frequencies greater than or less than said middle frequencies can vary (be attenuated) as the square root of a raised cosine function.

Lastly, the invention is an 8-level vestigial sideband (8VSB) filter comprising: means for filtering an input signal to produce a first signal; means for producing a second signal that has (1) zero amplitude when the first signal has an amplitude that is between first and second threshold values and (2) an amplitude equal to the first signal minus one of the threshold values when the first signal has an amplitude that is not between the first and second threshold values; and means for producing a third signal that is responsive to the first signal and the second signal.

The filter can further include means for amplifying the second signal, wherein the second signal that the means for producing the third signal is responsive to is the amplified second signal.

The means for producing the third signal can combine the amplified second signal and the first signal to produce the third signal.

The filter can further include means for bandpass filtering the third signal to produce a fourth signal.

The filter can further include at least one of the following: means for bandpass filtering the amplified second signal that is operative on by the means for producing the third signal; and means for delaying the propagation of the first signal that is operative on by the means for producing the third signal.

The means for amplifying can amplify the second signal about 2 times.

The means for filtering can utilize a square root raised cosine bandpass to filter the input signal.

The gain at the middle frequencies passable by said means for filtering can be constant and can vary (be attenuated) as the square root of a raised cosine function at frequencies on opposite sides of said middle frequencies with increasingly distance therefrom.

### BRIEF DESCRIPTION OF THE DRAWINGS

FIG. 1 is a graph of peak-to-average power ratio (dB) versus percentage of time peak power is above average power of 8 level vestigial side band (8VSB) signals;

FIG. 2 is a block diagram of a prior art 8VSB filter for use in FM broadcasting;

FIG. 3 is a block diagram of a first embodiment 8VSB filter in accordance with the present invention; and

FIG. 4 is a block diagram of a second embodiment 8VSB filter in accordance with the present invention.

### DETAILED DESCRIPTION OF THE INVENTION

The present invention will be described with reference to the accompanying figures where like reference numbers correspond to like elements.

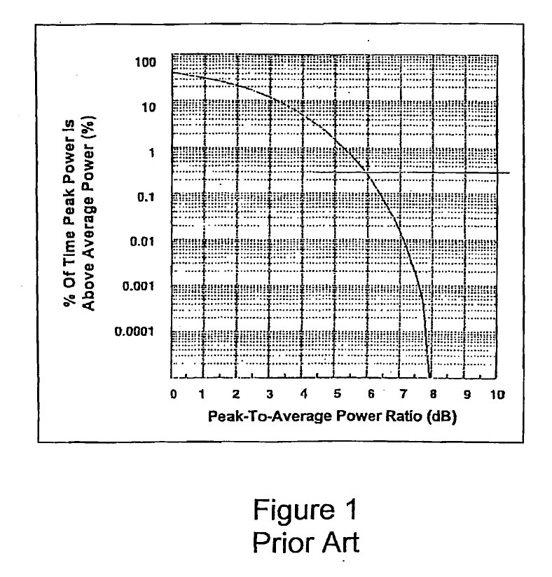

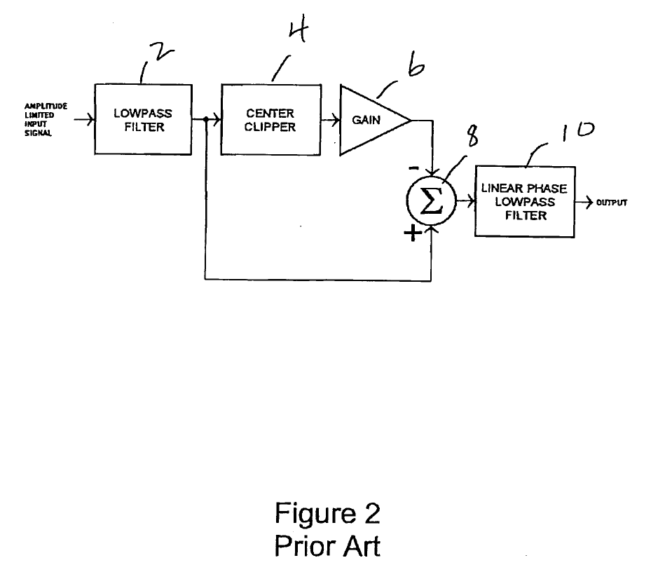

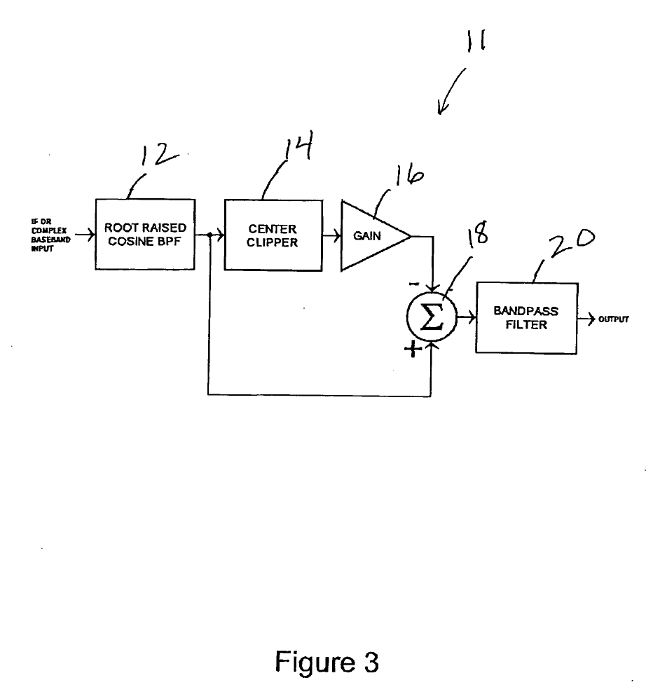

With reference to FIG. 3, the prior art method discussed above in connection with FIGS. 1 and 2 may be adapted and modified to work with 8VSB bandpass filters or baseband filters operating on complex baseband signals.

Specifically, a modulated complex baseband or IF input signal is applied to a square root raised cosine bandpass filter 12 that is part of an 8VSB filter 11 in accordance with the present invention. The gain at the middle frequencies passable by square root raised cosine bandpass filter 12 is constant. The gain at frequencies on opposites sides of the middle frequencies passable by the square root raised cosine bandpass filter (i.e., at frequencies greater than and less than said middle frequencies) can vary (decrease) according to a square root raised cosine function. Square root raised cosine bandpass filter 12 can be implemented as a single filter or as two cosine bandpass filters (not shown) connected in series. The input signal to filter 12 is quantized to a predetermined number, e.g., without limitation, 8, discrete levels. The output of filter 12, however, will include transients that may significantly exceed even the highest quantized level.

As determined by the headroom characteristics of the transmitter (not shown) that utilizes the output of 8VSB filter 11, a threshold point will be set for a center clipper 14 of 8VSB filter 11. The center-clipped peaks output by center clipper 14 will be amplified by amplifier 16 by a factor of about 2, and then subtracted by summing circuit 18 from the output of filter 12. The output of summing circuit 18 will be filtered by bandpass filter 20 to remove out-of-band nonlinear components generated by center clipper 14.

It has been observed that amplifier 16 having a linear gain of about 2 works well for signals that only require a few decibels of peak control (up to about 3 dB). For larger values of peak control, or for more accurate control of small amounts of peak reduction, amplifier 16 may be modified to have a nonlinear function. Desirably, small overshoots should have something more than the gain of 2 applied, while large overshoots should have the gain reduced to something less than the nominal value of 2.

In the case of a complex baseband signal, 8VSB filter 11 will act on complex numbers rather than simple real values. Center clipper 14 will respond to the modulus of the complex values being applied (that is, the square root of the sum of the squares of the real and imaginary parts).

Although 8VSB filter 11 shown in FIG. 3 will accurately limit envelope peaks, the requirements placed on the output side of bandpass filter 20 are stringent, because the transmitted signal passes through it.

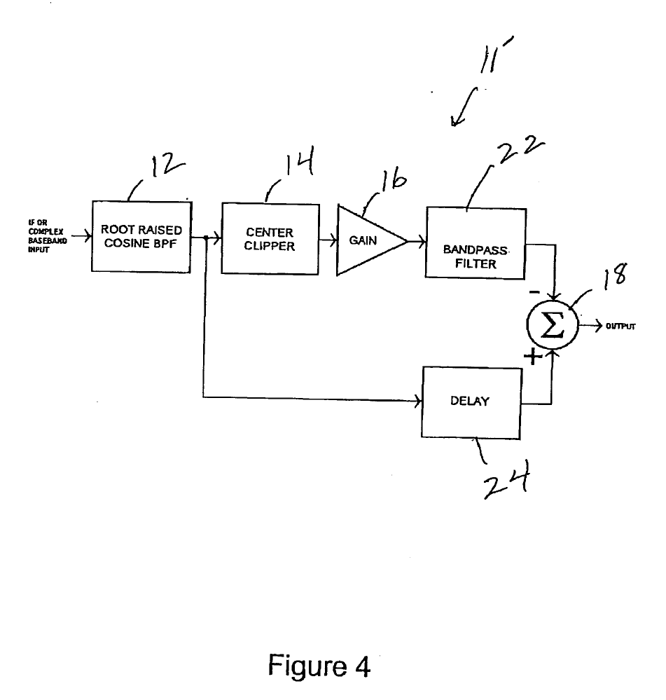

With reference to FIG. 4 and with continuing reference to FIG. 3, another embodiment 8VSB filter 11′ includes square root raised cosine bandpass filter 12, center clipper 14 and amplifier 16 connected in the same manner as like numbered components in FIG. 3. In contrast to 8VSB filter 11 shown in FIG. 3, however, in 8VSB filter 11′, the output of amplifier 16 is processed by a bandpass filter 22 before reaching the negative (−) input of summing circuit 18. Moreover, the output of square root raised cosine bandpass filter 12 is coupled to the non-inverting input of summing circuit 18 via a delay filter 24 which suitably delays the arrival of the signal output by the square root raised cosine bandpass filter 12 at the positive (+) input of summing circuit 18. The output of summing circuit 18 of 8VSB filter 11′ is similar to the output of 8VSB filter 11. An advantage of 8VSB filter 11′ shown in FIG. 4 is that bandpass filter 22 can have relaxed specifications, in terms of bandpass ripple, phase linearity, out of band attenuation, etc., over bandpass filter 20.

Compared with prior art 8VSB filters that reduce the peak-to-average ratio of complex digital signals, the 8VSB filters of the present invention will more accurately control peaks since post-clipping filtering will not overshoot nearly as much as it does with the prior art 8VSB filters. Therefore, less clipping may be applied to achieve a given level of peak-to-average ratio reduction. When incorporated into a transmitter, the 8VSB filters of the present invention enable said transmitters to output approximately 20% more useable power than said transmitters were capable of outputting without the 8VSB filters of the present invention.

The present invention has been described with reference to the preferred embodiments. Obvious modifications and alterations will occur to others upon reading and understanding the preceding detailed description. It is intended that the invention be construed as including all such modifications and alterations insofar as they come within the scope of the appended claims or the equivalents thereof.

The invention claimed is:

1. An 8-level vestigial sideband (8VSB) filter comprising:
a bandpass filter for processing an input signal to produce a first bandpass filtered output signal;
a center clipper circuit responsive to first and second threshold values and the first bandpass filtered output signal to produce a center clipper output signal that has (1) zero amplitude when the bandpass filtered output signal has an amplitude that is between the first and second threshold values and (2) an amplitude equal to an amplitude of the bandpass filtered output signal minus a value of one of the threshold values when the bandpass filtered output signal has an amplitude that is not between the first and second threshold values; and
a summing circuit having a first input responsive to the center clipper output signal and a second input responsive to the first bandpass filtered output signal for producing a summing circuit output signal related to the center clipper output signal and the first bandpass filtered output signal.

2. The filter of claim 1, further including an amplifier for amplifying the center clipper output signal and for providing said amplified center clipper output signal to the first input of the summing circuit.

3. The filter of claim 2, wherein the summing circuit subtractively combines the amplified center clipper output signal and the first bandpass filtered output signal to produce the summing circuit output signal.

4. The filter of claim 1, further including another bandpass filter operative for bandpass filtering the summing circuit output signal to produce a second bandpass filtered output signal.

5. The filter of claim 2, further including at least one of the following:
another bandpass filter operative for bandpass filtering the amplified center clipper output signal and for outputting the bandpass filtered amplified center clipper output signal to the first input of the summing circuit; and
a delay circuit operative for delaying the arrival of the first bandpass filtered output signal at the second input of the summing circuit.

6. The filter of claim 2, wherein the amplifier has a gain of about 2.

7. The filter of claim 1, wherein:
low frequencies attenuateable by the bandpass filter include ω<ω_{c}(1−α);
middle frequencies passable by the bandpass filter include ω_{c}(1−α)<ω<ω_{c}(1+α); and
high frequencies attenuateable by the bandpass filter include ω<ω_{c}(1−α), wherein:
ω is a frequency passable by the bandpass filter;
ω_{c} is the center frequency of the bandpass filter; and
0<α<1.

8. The filter of claim 1, wherein:
the bandpass filter is a square root raised cosine bandpass filter;
the gain at the middle frequencies passable by the square root raised cosine bandpass filter is constant; and
the gain at frequencies on opposites sides of said middle frequencies varies (decreases) according to a square root raised cosine function.

9. An 8-level vestigial sideband (8VSB) filtering method comprising:
(a) filtering an input signal to produce a first signal;
(b) producing a second signal that has (1) zero amplitude when the first signal has an amplitude that is between first and second threshold values and (2) an amplitude equal to the first signal minus one of the threshold values when the first signal has an amplitude that is not between the first and second threshold values; and
(c) producing a third signal that is responsive to the combination of the first signal and the second signal.

10. The method of claim 9, further including amplifying the second signal, wherein in step (c) the second signal is the amplified second signal.

11. The method of claim 10, wherein step (c) includes combining the amplified second signal and the first signal to produce the third signal.

12. The method claim 9, further including bandpass filtering the third signal to produce a fourth output signal.

13. The method of claim 10, further including at least one of the following:
bandpass filtering the amplified second signal, wherein in step (c) the second signal is the bandpass filtered and amplified second signal; or
delaying the propagation of the first signal prior to step (c).

14. The method of claim 10, wherein the second signal is amplified by a gain of about 2.

15. The method of claim 9, wherein:
low frequencies attenuateable by the filtering of step (a) include ω<ω_{c}(1−α);
middle frequencies passable by the filtering of step (a) include ω_{c}(1−α)<ω<ω_{c}(1+α); and
high frequencies attenuateable by the filtering of step (a) include ω<ω_{c}(1−α), wherein:
ω is a frequency passable by the bandpass filter;
ω_{c} is the center frequency of the bandpass filter; and
0<α<1.

16. The method of claim 9, wherein:
the input signal is square root raised cosine bandpass filtered;
the gain at the middle frequencies of the square root raised cosine bandpass filtered input signal is constant; and
the gain at frequencies on opposites sides of said middle frequencies varies (decreases) according to a square root raised cosine function.

17. An 8-level vestigial sideband (8VSB) filter comprising:
means for filtering an input signal to produce a first signal;
means for producing a second signal that has (1) zero amplitude when the first signal has an amplitude that is between first and second threshold values and (2) an amplitude equal to the first signal minus one of the threshold values when the first signal has an amplitude that is not between the first and second threshold values; and
means for producing a third signal that is responsive to the first signal and the second signal.

18. The filter of claim 17, further including means for amplifying the second signal, wherein the second signal that the means for producing the third signal is responsive to is the amplified second signal.

19. The filter of claim 18, wherein the means for producing the third signal combines the amplified second signal and the first signal to produce the third signal.

20. The filter of claim 17, further including means for bandpass filtering the third signal to produce a fourth signal.

21. The filter of claim 18, further including at least one of the following:
means for bandpass filtering the amplified second signal operative on by the means for producing the third signal; and
means for delaying the propagation of the first signal operative on by the means for producing the third signal.

22. The filter of claim 18, wherein the means for amplifying amplifies the second signal about 2 times.

23. The filter of claim 17, wherein:
the means for filtering utilizes a square root raised cosine bandpass filter to filter the input signal; and
the gain is constant at the middle frequencies passable by said means for filtering and varies as the square root of a raised cosine function at frequencies on opposite sides of said middle frequencies.
